(19) United States
(12) Patent Application Publication
(10) Pub. No.: US 2026/0005696 A1
(43) Pub. Date: Jan. 1, 2026

(54) OSCILLATOR SYNCHRONIZATION

(71) Applicant: Texas Instruments Incorporated, Dallas, TX (US)

(72) Inventors: Karthikeyan GUNASEKARAN, Bangalore (IN); Jagannathan VENKATARAMAN, Bangalore (IN); Snehasish ROYCHOWDHURY, Bengaluru (IN)

(73) Assignee: Texas Instruments Incorporated, Dallas, TX (US)

(21) Appl. No.: 18/756,216

(22) Filed: Jun. 27, 2024

(51) Int. Cl. H03L 7/099; H03K 3/0233; H03L 7/14

(52) U.S. Cl. CPC H03L 7/099; H03L 7/146

(57) ABSTRACT

A circuit includes an injection locking oscillator circuit and a sense circuit. The injection locking oscillator circuit has an input and an output. The sense circuit includes a sampling circuit and a comparator. The sampling circuit has a first input coupled to the input of the injection locking oscillator circuit, a second input coupled to output of the injection locking oscillator circuit, and an output. The comparator has an input coupled to the output of the sampling circuit, and an output.

### BACKGROUND

An oscillator is an electronic circuit that generates an oscillating signal. The oscillating signals can be generated in various ways. For example, Inductor-capacitor oscillators, crystal oscillators, voltage controlled oscillators, or phase-locked loops may be used for generating an oscillating signal. Oscillating signals may be required in various applications. For example, processors require clock signals and transceivers require oscillator signals for transmission and reception of signals.

### SUMMARY

In one example, a circuit includes an injection locking oscillator circuit and a sense circuit. The injection locking oscillator circuit has an input and an output. The sense circuit includes a sampling circuit and a comparator. The sampling circuit has a first input coupled to the input of the injection locking oscillator circuit, a second input coupled to output of the injection locking oscillator circuit, and an output. The comparator has an input coupled to the output of the sampling circuit, and an output.

In another example, a circuit includes an injection locking oscillator circuit and a phase control circuit. The injection locking oscillator circuit includes a first amplifier and a second amplifier. The first amplifier has a first input, a second input, a first output, and a second output. The second amplifier has a first input, a second input, a first output, and a second output. The first input of the second amplifier is coupled to the first output of the first amplifier. The second input of the second amplifier is coupled to the second output of the first amplifier. The first output of the second amplifier is coupled to the first input of the second amplifier. The second output of the second amplifier is coupled to the second input of the second amplifier. The phase control circuit is coupled to the injection locking oscillator. The phase control circuit is configured to adjust an output clock of the injection locking oscillator circuit to a selected phase.

In a further example, a transceiver circuit includes a transmitter circuit. The transmitter circuit includes a synchronizing injection locking oscillator (SILO) circuit. The SILO circuit is configured to provide a SILO output clock. The SILO circuit includes an injection locking oscillator (ILO) circuit, a sense circuit, and a correction circuit. The ILO circuit has an input configured to receive a locking signal, and an output. The ILO circuit is configured to provide, at the output, an ILO output clock having a frequency based on a frequency of a locking signal. The sense circuit is coupled to the ILO circuit. The sense circuit is configured to sense a phase of the ILO output clock relative to the locking signal, and provide a phase signal representing the phase. The correction circuit is coupled to the sense circuit and the ILO circuit. The correction circuit is configured to adjust a phase of the SILO output clock based on the phase signal.

### BRIEF DESCRIPTION OF THE DRAWINGS

FIG. 1 is a block diagram of an example synchronized injection locking oscillator.

FIG. 2 is a graph of example gain and oscillation in the injection locking oscillator of FIG. 1.

FIG. 3 is a block diagram of a first example synchronized injection locking oscillator.

FIG. 4 is a block diagram of a second example synchronized injection locking oscillator.

FIG. 5 is a block diagram of the synchronized injection locking oscillator of FIG. 4 showing detail of the sense circuit and the correction circuit.

FIG. 6 is a block diagram of a third example synchronized injection locking oscillator.

FIG. 7 is a block diagram of an example system that includes an injection locking oscillator and phase sensing.

FIG. 8 is a block diagram of an example time division duplexing transceiver that includes the synchronized injection locking oscillator of FIG. 3, 4, or 6.

### DETAILED DESCRIPTION

Some radio frequency (RF) transceiver applications implement a time division duplexing (TDD) operation in which transmission and reception are performed in different time slots. To reduce power consumption in TDD, transmitter circuitry is powered off when the receiver circuitry is operating (powered on), and the receiver circuitry is powered off when the transmitter circuitry is operating. In some TDD applications, the phase of the oscillator used for transmission is preferably the same across different power cycles to facilitate tracking of symbol information or to align different transmitter outputs for beamforming. Injection locking oscillators may be used in some TDD applications to reduce jitter and phase noise.

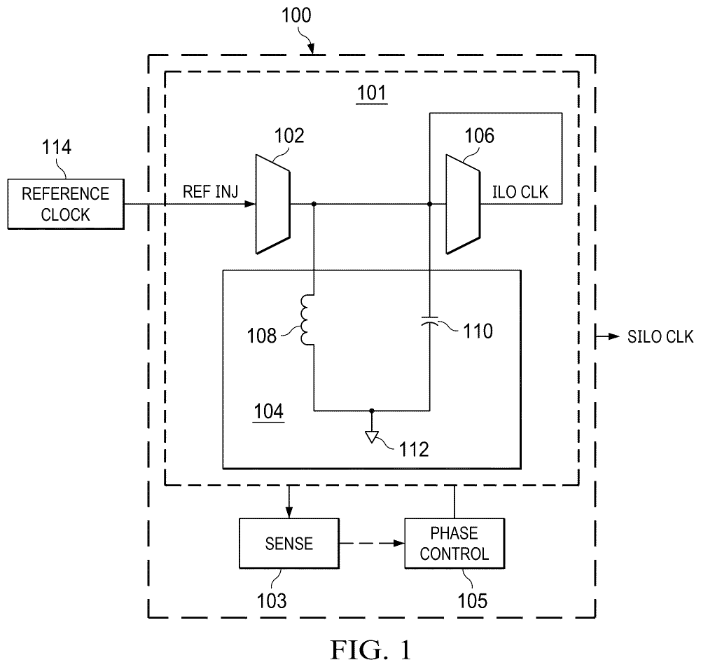

FIG. 1 is a block diagram of an example synchronized injection locking oscillator (SILO) circuit 100. The SILO circuit 100 includes an injection locking oscillator (ILO) circuit 101, a sense circuit 103, and a phase control circuit 105. The ILO circuit 101 includes an amplifier 102, an inductor-capacitor (L-C) tank circuit 104, and an amplifier 106. The L-C tank circuit 104 includes an inductor 108 and a capacitor 110. In some examples of the ILO circuit 101, the inductor 108 and the capacitor 110 are integrated on a same die as the amplifiers 102 and 106. In other examples of the ILO circuit 101, the inductor 108 and/or the capacitor 110 may be provided as discrete components that are separate from the integrated circuit that includes the amplifiers 102 and 106.

A first terminal of the inductor 108 is coupled to a first terminal of the capacitor 110 and to a reference terminal (e.g., ground 112 or a power terminal). A second terminal of the inductor 108 is coupled to a second terminal of the capacitor 110. The inductance of inductor 108 and the capacitance of the capacitor 110 may be selected to provide a desired resonant frequency. The example L-C tank circuit 104 includes one inductor and one capacitor coupled in parallel between the reference terminal and the coupling of an output of the amplifier 102 and an input of the amplifier 106. Other examples of an LC tank circuit may include a different coupling between the inductor and capacitor and/or additional inductors or capacitors coupled together to provide the desired resonant frequency.

An input of the amplifier 106 is coupled to the second terminal of the inductor 108, and an output of the amplifier 106 is coupled to the input of the amplifier 106. The amplifier 106 adds gain to the ILO circuit 101 to induce and maintain oscillation. The amplifier 106 may provide 180° of phase shift between its input and output (the amplifier 106 may be an inverting amplifier).

The amplifier 102 has an output coupled to the second terminal of the inductor 108, and an input coupled to a reference clock circuit 114 for receipt of a locking signal (REF INJ). The reference clock circuit 114 may be provided in circuitry that is external to the ILO circuit 101. The amplifier 102 provides a current based on the locking signal. Injection of the locking signal to the L-C tank circuit 104 can lock the frequency and phase of the oscillating signal (ILO CLK) generated by the ILO circuit 101 to the frequency and phase of the locking signal. The oscillating signal generated by the ILO circuit 101 may have a 50% duty cycle and symmetric rise and fall times.

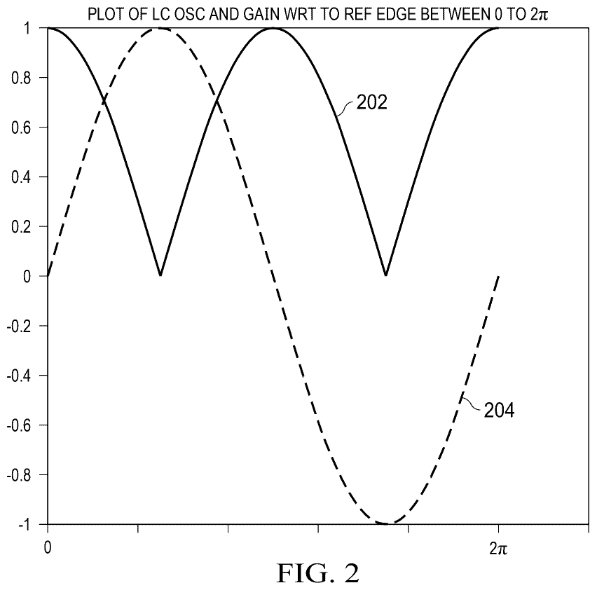

FIG. 2 is a graph of example gain and oscillation in the ILO circuit 101. FIG. 2 shows gain 202 and the oscillating signal 204 between 0 and 2TT, with gain and signal amplitude (0-1) on the y-axis, and phase (0-2TT) on the x-axis. Because the gain of the ILO circuit 101 (gain 202) is symmetric with respect to the rising and falling edges of the locking signal, the oscillating signal 204 can lock to either the rising or the falling edges of the locking signal, which causes uncertainty in the phase of the oscillating signal 204 generated by the ILO circuit 101. For example, the oscillating signal 204 may be as shown in FIG. 2, or shifted 180° relative to the oscillating signal 204 as shown in FIG. 2, and each time the ILO circuit 101 is powered in a TDD application, the oscillating signal 204 may be one of the two phases (e.g., 0° or 180°). Such phase uncertainty is undesirable in applications that require phase synchronicity at the system level (e.g., TDD applications).

The sense circuit 103 and/or the phase control circuit 105 are coupled to the ILO circuit 101 to control the phase of the SILO output clock (SILO CLK) generated by the SILO circuit 100, or provide SILO CLK phase information to circuitry external to the SILO circuit 100, which allows the external circuitry to compensate for the phase of SILO CLK. The sense circuit 103 senses the phase of ILO CLK relative to REF INJ. The sense circuit 103 can generate a signal that represents the relative phase of ILO CLK. The phase control circuit 105 controls the phase of SILO CLK. In some examples of the SILO circuit 100, the phase control circuit 105 controls the phase of SILO CLK based on the phase of ILO CLK indicated by a signal provided by the sense circuit 103. Some examples of the SILO circuit 100 lack the sense circuit 103, and the phase control circuit 105 controls the phase of the SILO CLK without sensing of ILO CLK phase. Some examples of the SILO circuit 100 lack the phase control circuit 105, and the sense circuit 103 provides a signal indicative of ILO CLK phase to external circuitry. The examples of the SILO circuit 100 described herein provide the SILO CLK with a same phase at each power cycle of the SILO circuit 100, or provide phase information that allows external circuitry to compensate for the phase of SILO CLK.

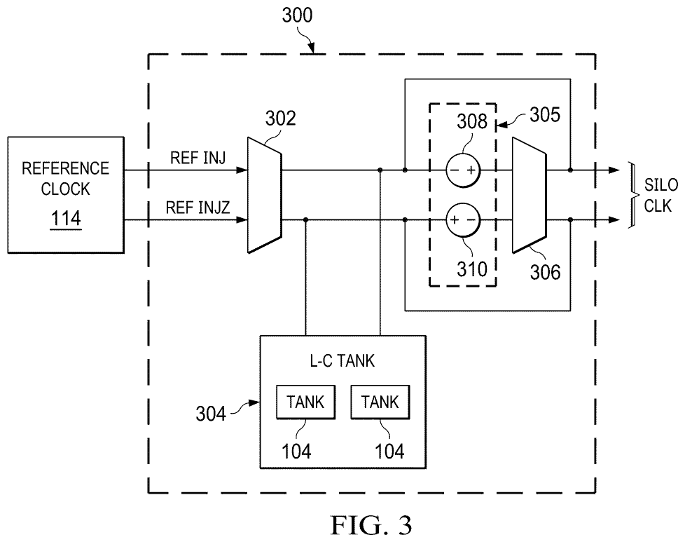

FIG. 3 is a block diagram of an example SILO circuit 300. The SILO circuit 300 is an example of the SILO circuit 100. The SILO circuit 300 includes an amplifier 302, an L-C tank circuit 304, an amplifier 306, and a phase control circuit 305. The phase control circuit 305 is an example of the phase control circuit 105, and includes voltage sources 308 and 310. The amplifier 302 and the amplifier 306 are fully differential. The example L-C tank circuit 304 includes a first L-C tank circuit 104 coupled to a first output of the amplifier 302, and a second L-C tank circuit 104 coupled to a second output of the amplifier 302.

The voltage source 308 is coupled between the first output of the amplifier 302 and a first input of the amplifier 306. The voltage source 310 is coupled between the second output of the amplifier 302 and a second input of the amplifier 306. A negative terminal of the voltage source 308 is coupled to the first output of the amplifier 302, and a positive terminal of the voltage source 308 is coupled to the first input of the amplifier 306. A positive terminal of the voltage source 310 is coupled to the second output of the amplifier 302, and a negative terminal of the voltage source 310 is coupled to the second input of the amplifier 306. A first output of the amplifier 306 is coupled to the negative terminal of the voltage source 308. A second output of the amplifier 306 is coupled to the positive terminal of the voltage source 310. In some examples of the SILO circuit 300, the voltage sources 308 and 310 are implemented using transistors with different threshold voltages coupled to or in the inputs of the amplifier 302. A transistor having a first (e.g., lower) threshold voltage implements the voltage source 308, and a transistor with a second (e.g., higher) threshold voltage implements the voltage source 310.

The voltage sources 308 and 310 change the symmetry in gain with respect to rising and falling edges to favor one edge over the other. Accordingly, the SILO circuit 300 reduces the probability of the oscillating signal generated by the SILO circuit 300 aligning to any edge of the locking signal, and instead causes the SILO circuit 300 to generate an oscillating signal that is always aligned to a same edge of the locking signal, for example, when using TDD. While the SILO circuit 300 can eliminate the issue of indeterminate phase, some implementations of the SILO circuit 300 may exhibit increased second harmonic distortion relative to other ILO implementations.

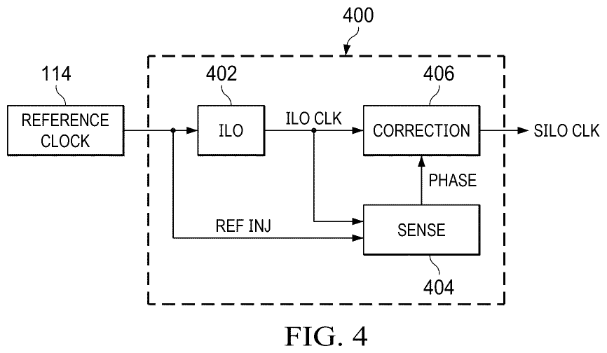

FIG. 4 is a block diagram of an example SILO circuit 400. The SILO circuit 400 includes an ILO circuit 402, a sense circuit 404, and a correction circuit 406. The ILO circuit 402 may be an example of the ILO circuit 101. The sense circuit 404 may be an example of the sense circuit 103. The correction circuit 406 may be an example of the phase control circuit 105. An output of the ILO circuit 402 is coupled to an input of the sense circuit 404 and an input of the correction circuit 406. An output of the reference clock circuit 114 is coupled to an input of the ILO circuit 402 and an input of the sense circuit 404.

An output of the sense circuit 404 is coupled to an input of the correction circuit 406. The sense circuit 404 determines the phase of the oscillating signal (ILO CLK) generated by the ILO circuit 402 relative to the locking signal (REF INJ). At the output of the sense circuit 404, the sense circuit 404 provides a phase signal (PHASE) that represents the determined phase of ILO CLK. Based on the phase signal received from the sense circuit 404, the correction circuit 406 can adjust the phase of ILO CLK to produce SILO CLK. SILO CLK is, thereby, synchronized in frequency to REF INJ, and is provided with a same phase relative to REF INJ each time the SILO circuit 400 is powered.

Some examples of the SILO circuit 400 may lack the correction circuit 406. In such examples, circuitry external to the SILO circuit 400 may apply the phase signal to determine the phase of ILO CLK, and adjust for the phase in digital signal processing.

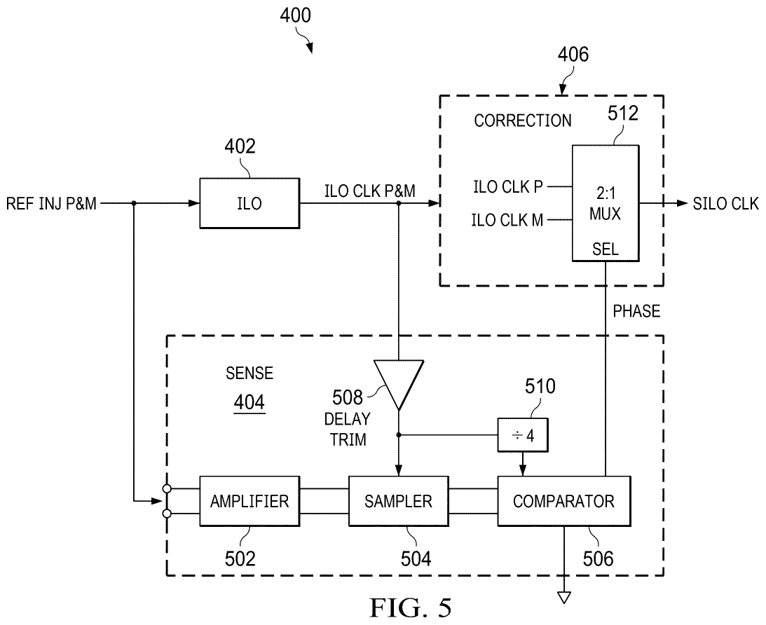

FIG. 5 is a block diagram of the SILO circuit 400 showing details of the sense circuit 404 and the correction circuit 406. In FIG. 5, the SILO circuit 400 is differential, similar to the SILO circuit 300. The ILO circuit 402 receives the differential lock signals REJ INJ P and REF INJ M provided by the reference clock circuit 114. The sense circuit 404 includes an amplifier 502, a sampling circuit 504, a comparator 506, a delay circuit 508, and a frequency divider circuit 510. The amplifier 502 buffers REF INJ P&M to reduce loading of the reference clock circuit 114. Inputs of the amplifier 502 are coupled to outputs of the reference clock circuit 114. The amplifier 502 may include source follower circuits to buffer REF INJ P&M. The amplifier 502 has outputs at which the amplifier 502 provides buffered REF INJ P&M.

The sampling circuit 504 has inputs coupled to the outputs of the amplifier 502. The sampling circuit 504 also has a third input coupled to the output of the ILO circuit 402 via the delay circuit 508. For example, the third input of the sampling circuit 504 may be coupled to the ILO CLK P output of the ILO circuit 402 via the delay circuit 508. The delay circuit 508 has an input coupled to an output of the ILO circuit 402, and an output coupled to the third input of the sampling circuit 504. The delay circuit 508 may delay ILO CLK P by a time selected to match the delay of the amplifier 502. The sampling circuit 504 samples the delayed ILO output clock (delayed ILO CLK P) with timing controlled by the buffered REF INJ P&M. For example, the sampling circuit 504 applies buffered REF INJ P&M as a sampling clock to sample the delayed ILO CLK P. The sampling circuit 504 has first and second outputs (e.g., differential outputs) at which a sample signal representing the sampled ILO CLK is provided.

The sample signal provided at the outputs of the sampling circuit 504 is a DC voltage that represents the phase of ILO CLK relative to REF INJ. For example, if the ILO CLK is about the same phase (e.g., 0° phase shift) as REF INJ, then the sample signal may be greater than zero volts. If ILO CLK is shifted in phase (e.g., 180° phase shift) relative to REF INJ, then the sample signal may be less than zero volts. The comparator 506 has inputs coupled to the outputs of the sampling circuit 504 for receipt of the sample signal. A first input of the comparator 506 is coupled to a first output of the sampling circuit 504, and a second input of the comparator 506 is coupled to a second output of the sampling circuit 504 (e.g., for receipt of a differential sample signal).

The comparator 506 compares the sample signal received from the sampling circuit 504 to a reference voltage to generate a phase signal that represents the phase of ILO CLK relative to REF INJ. For example, the comparator 506 may compare the sample signal to zero volts provided at a reference voltage terminal (e.g., a ground terminal). The phase signal may have a first state (e.g., logic high) to represent the sample signal greater than the reference voltage (e.g., 0° phase shift). The phase signal may have a second state (e.g., logic low) to represent the sample signal less than the reference voltage (e.g., 180° phase shift). The output of the comparator 506 is coupled to an input of the correction circuit 406.

The comparator 506 may be latching comparator, with a control input coupled to an output of the frequency divider circuit 510. The frequency divider circuit 510 may divide the delayed ILO CLK by four, or other integer divisor value, to generate a frequency divided signal used as latching control signal by the comparator 506. For example, the comparator 506 may latch and hold the state of the phase signal if the latch control signal has a logic high state, and pass the phase signal with no latching if the latch control signal has a logic low state.

The correction circuit 406 can adjust the phase of the SILO CLK based on the phase signal received from the comparator 506. The correction circuit 406 includes a multiplexer 512. The multiplexer 512 has a first input coupled to the first output of the ILO circuit 402 for receipt of ILO CLK P, and a second input coupled to the second output of the ILO circuit 402 for receipt of ILO CLK M. The multiplexer 512 has a control input coupled to the output of the comparator 506. If the phase signal is a logic high, then the multiplexer 512 may pass ILO CLK uninverted to the output of the multiplexer 512, which is coupled to the output of the correction circuit 406. If the phase signal is a logic low, then the multiplexer 512 may pass ILO CLK inverted to the output of the multiplexer 512. Accordingly, the sense circuit 404 and the correction circuit 406 can provide SILO CLK with a 0° phase shift relative to REF INJ regardless of the phase of ILO CLK.

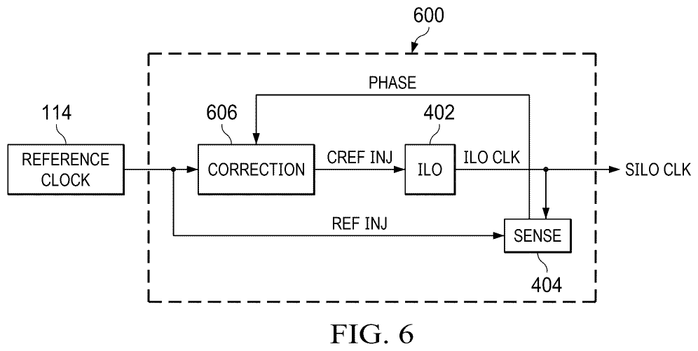

FIG. 6 is a block diagram of an example SILO circuit 600. The SILO circuit 600 includes the ILO circuit 402 and the sense circuit 404 as described with respect to the SILO circuit 400. The SILO circuit 600 also includes a correction circuit 606 coupled between the reference clock circuit 114 and the ILO circuit 402. The correction circuit 606 is an example of the phase control circuit 105. The correction circuit 606 has an input coupled to the output of the reference clock circuit 114 for receipt of REF INJ, and output coupled to the input of the ILO circuit 402. For a differential locking signal, the correction circuit 606 may have first and second inputs coupled to first and second outputs of the reference clock circuit 114, or first and second locking signal terminals. The correction circuit 606 provides a corrected version of REF INJ (CREF INJ) at the output of the correction circuit 606.

The sense circuit 404 operates as described with respect to the SILO circuit 400, and provides the phase signal (PHASE) to the correction circuit 606. An input of the correction circuit 606 is coupled to the output of the sense circuit 404 for receipt of the phase signal. The correction circuit 606 may be similar to the correction circuit 406. If the phase signal is a logic high, then the correction circuit 606 may pass REF INJ uninverted to the output of the correction circuit 606 (CREF INJ has the same phase as REF INJ). If the phase signal is a logic low, then the correction circuit 606 may pass REF INJ inverted to the output of the correction circuit 606 (CREF INJ is 180 phase shifted relative to REF INJ). Accordingly, if the sense circuit 404 determines that ILO CLK is not the same phase as REF INJ, then the correction circuit 606 inverts CREF INJ to cause the ILO circuit 402 to invert ILO CLK. The SILO circuit 600 can provide SILO CLK with a 0° phase shift relative to REF INJ regardless of the initial phase of ILO CLK.

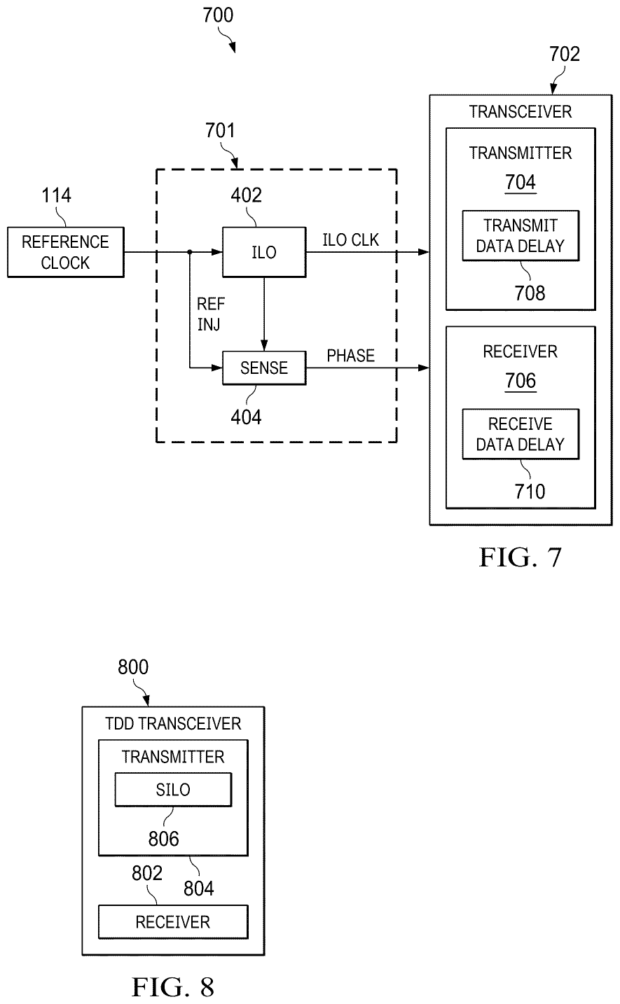

FIG. 7 is a block diagram of an example system 700. The system 700 includes an oscillator circuit 701 and a transceiver circuit 702. The oscillator circuit 701 includes the ILO circuit 402 and the sense circuit 404. The ILO circuit 402 and the sense circuit 404 operate as described with respect to the SILO circuit 400. The oscillator circuit 701 does not include a correction circuit. Accordingly, ILO CLK provided by the oscillator circuit 701 may have either 0° or 180° of phase shift relative to REF INJ each time the ILO circuit 402 is power cycled. The phase signal (PHASE) provided by the sense circuit 404 specifies the phase of ILO CLK relative to REF INJ.

The transceiver circuit 702 includes a transmitter circuit 704 and a receiver circuit 706. The transmitter circuit 704 may provide data for transmission by an RF transmitter, and the receiver circuit 706 may receive data from an RF receiver and provide the received data to circuitry coupled to the transceiver circuit 702 (not shown). The transmitter circuit 704 includes a transmit data delay circuit 708 that compensates for the phase of ILO CLK. The transmit data delay circuit 708 may include a digital filter or a memory-based delay that adds a delay time of about one-half cycle time of the ILO CLK to the digital data to be transmitted if the phase signal indicates that ILO CLK has 180° of phase shift relative to REF INJ. The transmit data delay circuit 708 may add no delay to the digital data to be transmitted if the phase signal indicates that ILO CLK has 0° of phase shift relative to REF INJ. The transmitter circuit 704 may provide the digital data delayed by the transmit data delay circuit 708 to a digital-to-analog converter for generation of an analog signal to be transmitted.

The receiver circuit 706 includes a receive data delay circuit 710 that compensates for the phase of ILO CLK. The receive data delay circuit 710 may include a filter or a memory-based delay that adds a delay time equal to about one-half cycle time of the ILO CLK to received digital data if the phase signal indicates that ILO CLK has 180° of phase shift relative to REF INJ. The receive data delay circuit 710 may add no delay to the received digital data if the phase signal indicates that ILO CLK has 0° of phase shift relative to REF INJ. The receiver circuit 706 may provide digital data delayed by the receive data delay circuit 710 to circuitry external to the transceiver circuit 702 for processing.

FIG. 8 is a block diagram of an example TDD transceiver circuit 800. The TDD transceiver circuit 800 can be applied in a cellular base station or other RF system that uses time division duplexing. The TDD transceiver circuit 800 includes a receiver circuit 802 and a transmitter circuit 804. The transmitter circuit 804 includes a SILO circuit 806. The SILO circuit 806 may be an example of the SILO circuit 300, the SILO circuit 400, or the SILO circuit 600. The receiver circuit 802 receives RF signals transmitted by a device external to the TDD transceiver circuit 800 and provides received data to circuitry external to the TDD transceiver circuit 800. If the receiver circuit 802 is active (e.g., powered on), then the transmitter circuit 804, including the SILO circuit 806, may be powered off to reduce power consumption. Similarly, if the transmitter circuit 804 is active (e.g., powered on), then the receiver circuit 802 may be powered off to reduce power consumption. Each time the transmitter circuit 804 is powered on, the SILO circuit 806 provides SILO CLK having a same phase (e.g., a same phase as REF INJ), and the phase of signals transmitted by the transmitter circuit 804 is known, which enables use of the TDD transceiver circuit 800 in beamforming. In some examples of the TDD transceiver circuit 800, the receiver circuit 802 may include an example of the SILO circuit 806 to provide a same phase of clock with each power cycle of the receiver circuit 802.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET)) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. A circuit comprising:
an injection locking oscillator circuit having an input and an output;
a sense circuit including:
a sampling circuit having a first input coupled to the input of the injection locking oscillator circuit, a second input coupled to output of the injection locking oscillator circuit, and an output; and
a comparator having an input coupled to the output of the sampling circuit, and an output.

2. The circuit of claim 1, wherein the sense circuit includes a delay circuit having an input coupled to the output of the injection locking oscillator circuit, and an output coupled to the second input of the sampling circuit.

3. The circuit of claim 1, wherein the sense circuit includes an amplifier having an input coupled to the input of the injection locking oscillator circuit, and an output coupled to the first input of the sampling circuit.

4. The circuit of claim 1, wherein:
the sense circuit includes a frequency divider circuit having an input coupled to the second input of the sampling circuit, and an output; and
the input of the comparator is a first input, and the comparator has a second input coupled to the output of the frequency divider circuit.

5. The circuit of claim 1, further comprising a correction circuit having:
a first input coupled to the output of the injection locking oscillator circuit, wherein the output of the injection locking oscillator circuit is a first output, and the injection locking oscillator circuit has a second output;
a second input coupled to the second output of the injection locking oscillator circuit;
a third input coupled to the output of the comparator; and
an output.

6. The circuit of claim 5, wherein the correction circuit includes a multiplexer configured to:
pass a first signal from the first input of the correction circuit to the output of the correction circuit based on a phase signal at the third input having a first state; and
pass a second signal from the first input of the correction circuit to the output of the correction circuit based on the phase signal at the third input having a second state.

7. The circuit of claim 1, further comprising a correction circuit having:
a first input coupled to a first locking signal terminal;
a second input coupled to a second locking signal terminal;
a third input coupled to the output of the comparator; and
an output coupled to the input of the injection locking oscillator circuit.

8. The circuit of claim 1, wherein the injection locking oscillator circuit includes:
a first amplifier having an input coupled to the input of injection locking oscillator circuit, and an output coupled to the output of the injection locking oscillator circuit;
a second amplifier having an input coupled to the output of the first amplifier, and an output coupled to the output of the first amplifier; and
an inductor-capacitor tank circuit coupled to the output of the first amplifier.

9. A circuit comprising:
an injection locking oscillator circuit including:
a first amplifier having a first input, a second input, a first output, and a second output;
a second amplifier having a first input coupled to the first output of the first amplifier, a second input coupled to the second output of the first amplifier, a first output coupled to the first input of the second amplifier, and a second output coupled to the second input of the second amplifier; and
a phase control circuit coupled to the injection locking oscillator circuit, the phase control circuit configured to adjust an output clock of the injection locking oscillator circuit to a selected phase.

10. The circuit of claim 9, wherein the phase control circuit includes:
a first voltage source having a first terminal coupled to the first output of the first amplifier and the first output of the second amplifier, and a second terminal coupled to the first input of the second amplifier; and
a second voltage source having a first terminal coupled to the second output of the first amplifier and the second output of the second amplifier, and a second terminal coupled to the second input of the second amplifier.

11. The circuit of claim 10, wherein:
the first terminal of the first voltage source is a negative terminal, and the second terminal of the first voltage source is a positive terminal; and
the first terminal of the second voltage source is a positive terminal, and the second terminal of the second voltage source is a negative terminal.

12. The circuit of claim 9, further comprising a sense circuit having a first input coupled to the first output of the first amplifier, a second input configured to receive a locking signal, and an output.

13. The circuit of claim 12, wherein the phase control circuit includes a multiplexer having a first input coupled to the first output of the second amplifier, a second input coupled to the second output of the second amplifier, a control input coupled to the output of the sense circuit, and an output configured to provide the output clock.

14. The circuit of claim 12, wherein the phase control circuit includes a first input configured to receive a first locking signal, a second input configured to receive a second locking signal, a first output coupled to the first input of the first amplifier, a second output coupled to the second input of the first amplifier, and a control input coupled to the output of the sense circuit.

15. The circuit of claim 12, wherein the sense circuit includes:
a third amplifier having an input coupled to the first input of the sense circuit, and an output;
a sampling circuit having a first input coupled to the output of the third amplifier, a second input coupled to the second input of the sense circuit, and an output; and
a comparator having a first input coupled to the output of the sampling circuit, and an output.

16. The circuit of claim 15, wherein:
the comparator has a second input; and
the sense circuit includes:
a delay circuit having an input coupled to the second input of the sense circuit, and an output coupled to the second input of the sampling circuit, and
a frequency divider circuit having an input coupled to the output of the delay circuit, and an output coupled to the second input of the comparator.

17. A transceiver circuit comprising:
a transmitter circuit including a synchronizing injection locking oscillator (SILO) circuit configured to provide a SILO output clock, the SILO circuit including:
an injection locking oscillator (ILO) circuit having an input configured to receive a locking signal, and an output, the ILO circuit configured to provide, at the output, an ILO output clock having a frequency based on a frequency of a locking signal;
a sense circuit coupled to the ILO circuit, the sense circuit configured to sense a phase of the ILO output clock relative to the locking signal, and provide a phase signal representing the phase; and
a correction circuit coupled to the sense circuit and the ILO circuit, the correction circuit configured to adjust a phase of the SILO output clock based on the phase signal.

18. The transceiver circuit of claim 17, wherein the sense circuit includes:
an amplifier having an input configured to receive the locking signal, and an output;
a delay circuit having an input coupled to the output of the ILO circuit, and an output, the delay circuit configured to provide a delayed ILO output clock at the output of the delay circuit;
a sampling circuit having a first input coupled to the output of the amplifier, a second input coupled to the output of the delay circuit, and an output, the sampling circuit configured to sample the delayed ILO output clock based on the locking signal, and provide, at the output of the sampling circuit, a sample signal; and
a comparator having a first input coupled to the output of the sampling circuit, a second input, and an output, the comparator configured to compare the sample signal to a reference voltage, and provide a phase signal, at the output of the comparator, indicating that the ILO output clock has one of two phases relative to the locking signal; and
a frequency divider circuit having an input coupled to the output of the delay circuit, and an output coupled to the second input of the comparator, the frequency divider circuit configured provided a frequency divided signal by dividing the delayed ILO output clock by a divisor value.

19. The transceiver circuit of claim 17, wherein the correction circuit includes a multiplexer configured to:
provide a first phase of the ILO output clock to be the SILO output clock based on the phase signal having a first state; and
provide a second phase of the ILO output clock to be the SILO output clock based on the phase signal having a second state.

20. The transceiver circuit of claim 17, wherein the correction circuit includes a multiplexer configured to:
provide a first phase of the locking signal to the ILO circuit based on the phase signal having a first state; and
provide a second phase of the locking signal to the ILO circuit based on the phase signal having a second state.
